(19) United States
(12) Patent Application Publication
(10) Pub. No.: US 2013/0016749 A1
(43) Pub. Date: Jan. 17, 2013

(54) SURFACE EMITTING LASER DIODE

(71) Applicant: Takashi MOTODA, Tokyo (JP)

(72) Inventor: Takashi MOTODA, Tokyo (JP)

(73) Assignee: MITSUBISHI ELECTRIC CORPORATION, Tokyo (JP)

(21) Appl. No.: 13/397,926

(22) Filed: Feb. 16, 2012

(30) Foreign Application Priority Data
Jul. 13, 2011 (JP) 2011-154481

(51) Int. Cl. H01S 5/18

(52) U.S. Cl. 372/45.01

(57) ABSTRACT

A surface emitting laser diode includes: a semiconductor substrate; a first semiconductor layer of a first conductivity type on the semiconductor substrate; an active layer on the first semiconductor layer; a second semiconductor layer of a second conductivity type on the active layer; and a second order diffraction grating in one of the first semiconductor layer and the second semiconductor layer. The second order diffraction grating has a pattern which includes concentric circles, a spiral, or polygons. An active region including the first semiconductor layer, the active layer, and the second semiconductor layer, is circular or polygonal.

### BACKGROUND OF THE INVENTION

1. Field of the Invention

The present invention relates to a surface emitting laser diode.

2. Background Art

A surface emitting laser diode emits light perpendicular to its major surface. In a typical surface emitting diode, a linear diffraction grating is formed perpendicular to a laser stripe. Also, a surface emitting laser diode wherein a plurality of stripe-shaped active regions are radially arranged on a circular diffraction grating has been proposed (for example, refer to Japanese Patent Laid-Open No. 01-105590).

### SUMMARY OF THE INVENTION

In a conventional surface emitting laser diode, a horizontal far field pattern (FFP) differed from a vertical FFP. Also, high output light could not be outputted.

In view of the above-described problems, an object of the present invention is to provide a surface emitting laser diode which can emit high output light whose horizontal far field pattern and vertical far field pattern are the same.

According to the present invention, a surface emitting laser diode includes: a semiconductor substrate; a first semiconductor layer of a first conductivity type on the semiconductor substrate; an active layer on the first semiconductor layer; a second semiconductor layer of a second conductivity type on the active layer; and a second order diffraction grating in the first semiconductor layer or the second semiconductor layer. The second order diffraction grating has a pattern which includes concentric circles, a spiral, or a polygon. An active region including the first semiconductor layer, the active layer, and the second semiconductor layer is circular or polygonal.

The present invention makes it possible to emit high output light having the same horizontal far field pattern and vertical far field pattern.

Other and further objects, features and advantages of the invention will appear more fully from the following description.

### BRIEF DESCRIPTION OF THE DRAWINGS

FIG. 1 is a top view showing a surface emitting laser diode according to a first embodiment of the present invention.

FIG. 2 is a sectional view taken along the line I-II in FIG. 1.

FIG. 3 is a top view showing a first modified example of a surface emitting laser diode according to the first embodiment of the present invention.

FIG. 4 is a top view showing a second modified example of a surface emitting laser diode according to the first embodiment of the present invention.

FIG. 5 is a graph showing the wavelength of the active layer 3 and the wavelength of the two-dimensional diffraction grating 6.

FIG. 6 is a top view showing a surface emitting laser diode according to a second embodiment of the present invention.

FIG. 7 is a sectional view taken along the line I-II in FIG. 6.

FIG. 8 is a sectional view showing a surface emitting laser diode according to a third embodiment of the present invention.

FIG. 9 is a sectional view showing a surface emitting laser diode according to a fourth embodiment of the present invention.

FIG. 10 is a sectional view showing a surface emitting laser diode according to a fifth embodiment of the present invention.

FIG. 11 is a sectional view showing a surface emitting laser diode according to a sixth embodiment of the present invention.

### DETAILED DESCRIPTION OF THE PREFERRED EMBODIMENTS

A surface emitting laser diode according to the embodiments of the present invention will be described with reference to the drawings. The same components will be denoted by the same symbols, and repeated description thereof is omitted.

### First Embodiment

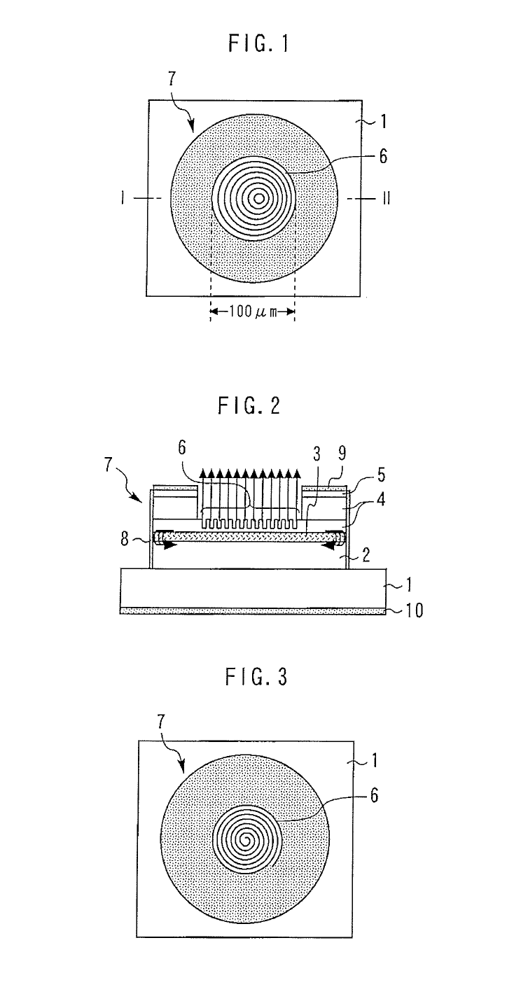

FIG. 1 is a top view showing a surface emitting laser diode according to a first embodiment of the present invention. FIG. 2 is a sectional view taken along the line I-II in FIG. 1.

On an n-type semiconductor substrate 1, an n-type clad layer 2, an active layer 3, a p-type clad layer 4, and a p-type contact layer 5 are sequentially laminated. The n-type semiconductor substrate 1 is GaAs or GaN. An n-type clad layer 2 and a p-type clad layer 4 are AlGaInP, AlGaAs, GaN, or the like. An active layer 3 is GaAs, AlGaAs, InGaP, AlGaInP, InGaN, GaN, or the like. A p-type contact layer 5 is of GaAs, GaN, or the like.

A second order diffraction grating 6 is present in the p-type clad layer 4. Here, if λ₀ denotes a Bragg wavelength, N_{eff} denotes the equivalent refractive index in a medium, and Λ denotes the period of the diffraction grating, the oscillation wavelength λ of a semiconductor laser is represented by λ=λ₀/N_{eff}=2Λ/m (m=1, 2, . . . ). The case wherein the integer m is 1 is a first order diffraction grating, and the case wherein the integer m is 2 is a second order diffraction grating. The period of the second order diffraction grating is twice the period of the first order diffraction grating.

In the present embodiment, the pattern of the second order diffraction grating 6 includes concentric circles having an outer diameter of 100 μm. The active region 7, including the n-type clad layer 2, the active layer 3, the p-type clad layer 4, and the p-type contact layer 5, is also circular in a top view. A high-reflectivity film 8 is located on the entire side surfaces of the active region 7. The high-reflectivity film 8 is gold, platinum, titanium, molybdenum, tantalum, nickel, or the like; or a multilayer film of these metals. The phase of the central portion of the second order diffraction grating 6 is shifted by ¼λ against the oscillation wavelength λ.

Above the second order diffraction grating 6, an annular p-side electrode 9 having a circular opening is located on the p-type contact layer 5. An n-side electrode 10 is located on the back face of the n-type semiconductor substrate 1. The p-side electrode 9 and the n-side electrode 10 are gold, platinum, titanium, molybdenum, tantalum, nickel, or the like; or may be a multilayer film of these metals.

The substrate used for LDs is selected in conformity with the material for the grown crystals. In the case of the AlGaInP system, the use of an off-axis substrate makes the crystallinity of the grown crystals better, and the light emitting efficiency of LDs higher. Although wet etching can be used for forming the circular patterns, dry etching makes the crystalline orientation dependency smaller, and facilitates etching circularly and vertically. Furthermore, wet etching and dry etching can be combined.

Next, the operation of the above-described surface emitting laser diode will be described. When a voltage is supplied between the p-side electrode 9 and the n-side electrode 10, light is generated in the active layer 3, and radiated to various directions. The radiated light resonates and oscillates at the side faces of the second order diffraction grating 6 and the active region 7. The oscillating light is output vertically in FIG. 2 from the upper surface, relative to the direction of the oscillator, by the second order diffraction grating 6.

Next, the effect of the present embodiment will be described. Since the second order diffraction grating 6 is circular and the active region 7 is also circular, the horizontal far field pattern and the vertical far field pattern of the emitted light has the same pattern. Furthermore, since light can be guided from all directions in the circular active region 7, high power output light can be emitted.

Furthermore, with regard to the oscillation wavelength λ, the phase of the center portion of the second order diffraction grating 6 is shifted by ¼λ. Thereby, single wavelength output light can be obtained.

In addition, the high-reflectivity film 8 covers the entire side face of the active region 7. The light not reflected by the second order diffraction grating 6 inside the active region 7 is reflected by the high-reflectivity film 8 in the peripheral portion of the active region 7. Thereby, the light emitting efficiency can be elevated. When the reflectance of the high-reflectivity film 8 is 100%, light is not emitted from the side surface of the active region 7, but is emitted only from the upper surface.

FIG. 3 is a top view showing a first modified example of a surface emitting laser diode according to the first embodiment of the present invention. The pattern of the second order diffraction grating 6 is spiral. Such a spiral pattern can be easily drawn by successively radiating EBs (Electron Beams).

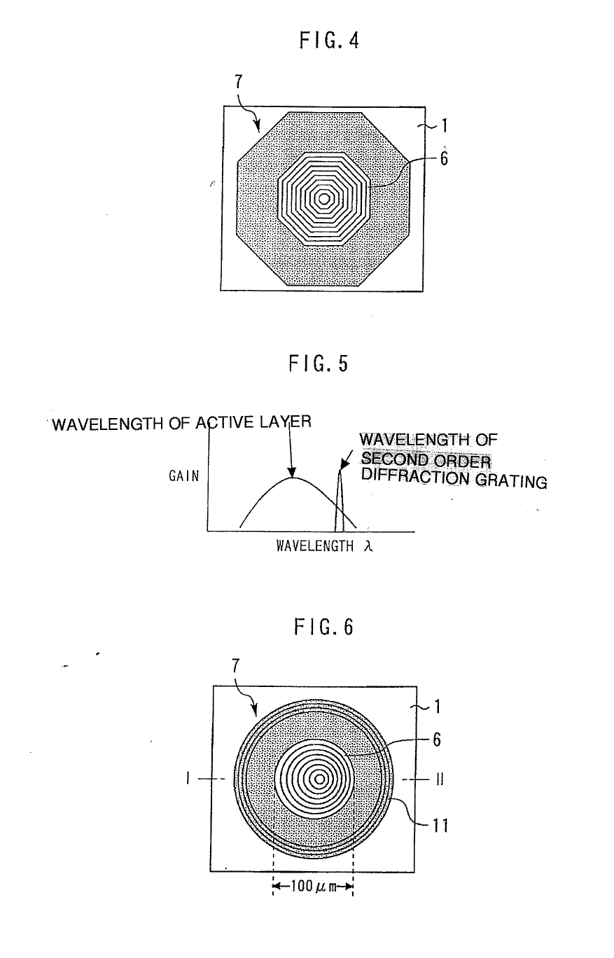

FIG. 4 is a top view showing a second modified example of a surface emitting laser diode according to the first embodiment of the present invention. The second order diffraction grating 6 and the active region 7 are octagonal. Therefore, light having octagonal cross-section can be emitted. The shape is not limited to octagonal, but by making the second order diffraction grating 6 and the active region 7 any polygonal shape, light having a desired polygonal cross-section can be output.

FIG. 5 is a graph showing the wavelength characteristic of the active layer 3, and the wavelength of the second order diffraction grating 6. The intersection of the wavelength characteristic of the second order diffraction grating and the wavelength characteristic of the active layer is made equal to a wavelength shorter than the band gap wavelength of the active layer 3, and light having a long wavelength is emitted. For example, in a GaN laser diode, the period of the second order diffraction grating 6 is made equal to the wavelength of pure blue light. Thereby, since the oscillation wavelength becomes shorter than the band-gap wavelength of the active layer 3, loss of light in the active layer 3 is decreased, and light can be emitted efficiently.

### Second Embodiment

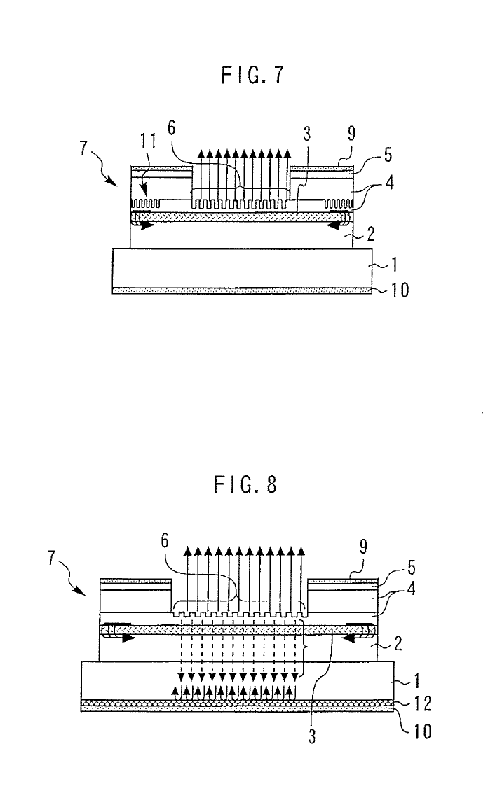

FIG. 6 is a top view showing a surface emitting laser diode according to a second embodiment of the present invention. FIG. 7 is a sectional view taken along the line I-II in FIG. 6. In place of the high-reflectivity film 8 of the first embodiment, a first order diffraction grating 11 with a reflectance of 100% is located at the peripheral portion of the active region 7. Thereby, without forming the high-reflectivity film 8, light can be reflected inwardly at the peripheral portion of the active region 7.

### Third Embodiment

FIG. 8 is a sectional view showing a surface emitting laser diode according to a third embodiment of the present invention. A high reflectivity film 12 is located on the back face of the semiconductor substrate 1. The high reflecting film 12 is gold, platinum, titanium, molybdenum, tantalum, or the like; or a multilayer film of these metals. By reflecting the light output from the second order diffraction grating 6 to the semiconductor substrate 1 side with the high reflectivity film 12, the light emitting efficiency from the upper surface can be improved.

Furthermore, the semiconductor substrate 1 has a larger band gap than the band gap of the active layer 3. Thereby, since the absorption of light by the semiconductor substrate 1 is decreased, light can be efficiently reflected from the back face of the semiconductor substrate 1.

### Fourth Embodiment

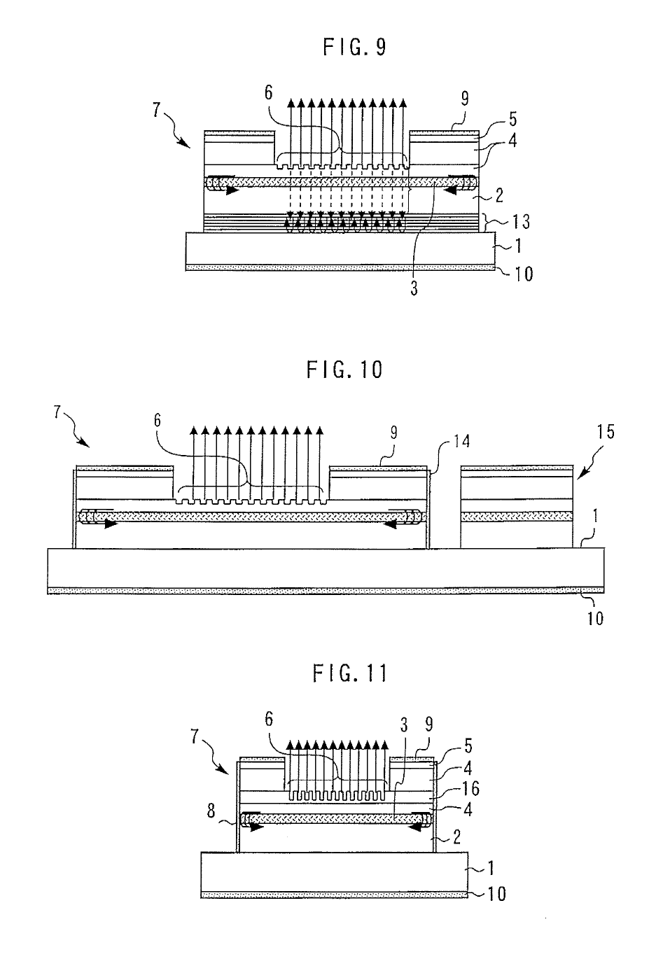

FIG. 9 is a sectional view showing a surface emitting laser diode according to a fourth embodiment of the present invention. A multilayer reflecting layer 13 including mutually laminated crystalline layers having different refractive indices is placed between the semiconductor substrate 1 and the n-type clad layer 2. The multilayer reflecting layer 13 is a multilayer film of, for example, AlGaInP or AlGaAs. By reflecting the light coming out from the second order diffraction grating 6 to the side of the semiconductor substrate 1 with the multilayer reflecting layer 13, the light emitting efficiency from the upper surface can be improved.

### Fifth Embodiment

FIG. 10 is a sectional view showing a surface emitting laser diode according to a fifth embodiment of the present invention. A half-mirror coating 14 is placed on the side surface of the active region 7. The half-mirror coating 14 reflects light from the interior of the active region 7, and transmits light from the exterior. Another laser diode 15 is integrated on the semiconductor substrate 1. Thereby, light from the other laser diode 15 can be incorporated into the active region 7, and surface emission can be feasible at even higher output.

The surface emitting laser diodes according to the first to fifth embodiments have a DBR (Distributed Bragg Reflector) structure wherein the second order diffraction grating 6 is located in part of the active region 7. However, the invention is not limited to this, but may be of a DFB (Distributed Feedback) structure wherein the second order diffraction grating 6 is located on the entire region of the active region 7. Furthermore, although the second order diffraction grating 6 is located in the p-type clad layer 4, the invention is not limited to this, and the second order diffraction grating 6 may be located in the n-type clad layer 2.

### Sixth Embodiment

FIG. 11 is a sectional view showing a surface emitting laser diode according to a sixth embodiment of the present invention. A light guiding layer 16 is located in the p-type clad layer 4, and a second order diffraction grating 6 is located in the light guiding layer 16. Other components are identical to those of the first embodiment. With this configuration as well, similar effects can be achieved. Furthermore, the light guiding layer 16 may be similarly located in the second to fifth embodiments, and diffraction gratings 6 and 11 may be located in the light guiding layer 16.

Although detailed epi-structures, such as the structure of the active layers have not been described in the first to sixth embodiments, the structure of the active layers may be an SQW (Single Quantum Well) or an MQW (Multi Quantum Well) structure. Furthermore, a structure having a band discontinuity relaxing layer, for relaxing the different band gaps between the clad layer and the contact layer, is also feasible.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2011-154481, filed on Jul. 13, 2011, including specification, claims, drawings, and summary, on which the Convention priority of the present application is based, is incorporated herein by reference in its entirety.

1. A surface emitting laser diode comprising:
a semiconductor substrate;
an active region on the semiconductor substrate, wherein
the active region has a periphery, when viewed perpendicular to the substrate, which is one of circular or polygonal,
the active region has a peripheral surface transverse to the semiconductor substrate along the periphery of the active region,
the active region includes, sequentially stacked on the semiconductor substrate,
a first semiconductor layer of a first conductivity type,
an active layer, and
a second semiconductor layer of a second conductivity type,
one of the first semiconductor layer and the second semiconductor layer includes a second order diffraction grating having a pattern which includes one of concentric circles, a spiral, and polygons; and
a reflective structure covering the peripheral surface and reflecting light generated in the active layer so that the light generated in the active layer resonates along directions parallel to the semiconductor substrate and the active layer and is radiated from the surface emitting laser by and through the second order diffraction grating in a direction perpendicular to the semiconductor substrate and the active layer.

2. The surface emitting laser diode according to claim 1, wherein phase of a central portion of the second order diffraction grating is shifted by ¼λ with respect to oscillation wavelength λ of the light generated in the active layer.

3. The surface emitting laser diode according to claim 1, wherein the reflective structure comprises a high-reflectivity film.

4. The surface emitting laser diode according to claim 1, wherein the reflective structure comprises a first order diffraction grating.

5. The surface emitting laser diode according to claim 1, further comprising a high-reflectivity film on a back face of the semiconductor substrate.

6. The surface emitting laser diode according to claim 5, wherein
the semiconductor substrate has a first band gap and the active layer has a second band gap, and
the first band gap is larger than the second band gap.

7. The surface emitting laser diode according to claim 1, wherein the active region includes a multilayer reflecting film located between the semiconductor substrate and the first semiconductor layer.

8. The surface emitting laser diode according to claim 1, wherein
the reflective structure comprises a half-mirror coating, and
the half-mirror coating reflects light within the active region and transmits light from outside the active region into the active region.

9. The surface emitting laser diode according to claim 8, further comprising a pumping semiconductor laser disposed on the semiconductor substrate proximate the surface emitting laser diode for emitting laser light supplied to the active region of the surface emitting laser diode through the half-mirror coating.

10. The surface emitting laser diode according to claim 1, wherein the second order diffraction grating has a spiral pattern.
